(19) United States
(12) Patent Application Publication
(10) Pub. No.: US 2025/0140702 A1
(43) Pub. Date: May 1, 2025

(54) POWER MODULE HAVING A FIRST CIRCUIT CARRIER CONTAINING A CARRIER SUBSTRATE

(71) Applicant: Robert Bosch GmbH, Stuttgart (DE)

(72) Inventor: Irfan Aydogmus, Nuertingen (DE)

(21) Appl. No.: 18/921,591

(22) Filed: Oct. 21, 2024

(30) Foreign Application Priority Data
Oct. 26, 2023 (DE) 10 2023 210 594.2

(51) Int. Cl. H01L 23/538; H01L 23/00; H01L 23/367; H01L 25/07

(52) U.S. Cl. CPC H01L 23/5383; H01L 23/3675; H01L 25/072; H01L 24/40; H01L 24/48; H01L 2224/40227; H01L 2224/48227

(57) ABSTRACT

A power module. The power module has a first circuit carrier including a carrier substrate and a first conductor structure having an external contact region, at least one second conductor structure having at least one external contact region and a further, third conductor structure including an external contact region. A first group of semiconductor elements and a second group of semiconductor elements are provided. The semiconductor elements arranged in groups in a second plane at the bottom of the power module are electrically connected via bonding wires and/or at least one contact strip to the T+ bridge and the phase bridge arranged in a first plane of a multifunctional frame.

### FIELD

The present invention relates to a power module having a first circuit carrier containing a carrier substrate, and a first conductor structure having an external contact region, at least one second conductor structure having at least one external contact region, and a further, third conductor structure comprising an external contact region.

### BACKGROUND INFORMATION

In the related art, power modules, which are installed for example in a power module bridge, are additionally molded. During molding, the power module is embedded in a solid protective housing, for example made of plastic (molding compound). The molding compound is used to enclose and protect the interior of the power module. However, these enclosures of the power module by means of molding compound are not particularly resistant to cracks.

German Patent Application No. DE 11 2017 004 390 T5 describes a power module that has the following features: an insulating substrate having a front side to which a power semiconductor element is fastened; a base plate connected to a rear side of the insulating substrate; a housing fastened to the base plate and surrounding the insulating substrate; a cover fastened to the housing and forming a sealed region; and a silicone gel serving as a filling element which fills the entire sealed region and has an internal stress that acts as a compressive stress.

German Patent Application No. DE 10 2014 219 998 B4 describes a power module, in particular for the provision of a phase current for an electric motor. The power module comprises a circuit carrier having a surface, at least two first contact faces on the surface, and at least two first power transistors, which each have a ground contact face. In each case, a first power transistor of the at least two first power transistors is arranged directly on one of the first contact faces and is electrically conductively connected directly to the relevant first contact face via its ground contact face. In addition, the power module comprises a second contact face on the surface and at least two second power transistors, which each have a ground contact face. The at least two second power transistors are arranged directly on the second contact face and are electrically conductively connected directly to the second contact face via their respective ground contact faces. Furthermore, the power module comprises at least two third contact faces on the surface, wherein the at least two second power transistors each have a further contact face on their sides facing away from the surface of the circuit carrier, and in each case one second power transistor of the at least two second power transistors is electrically conductively connected via its further contact face to one of the at least two third contact faces in each case. The at least two first contact faces and the at least two third contact faces are arranged alternately one after the other in a longitudinal direction of the power module, and the second contact face is arranged next to the at least two first contact faces and the at least two third contact faces, wherein the second contact face has at least two contact regions, wherein in each case one of the at least two contact regions is located next to one of the at least two first power transistors. The at least two first power transistors each comprise a further contact face on their sides facing away from the surface of the circuit carrier, and in each case one first power transistor of the at least two first power transistors is electrically conductively connected via its further contact face to the in each case one contact region, located next to it, of the at least two contact regions of the second contact face. In this case, the at least two contact regions of the second contact face and the at least two second power transistors are arranged alternately one after the other in the longitudinal direction.

European Patent No. EP 2 418 925 B1 describes electrical contacting between a flexible film, which has at least one conductor track, and at least one electrical contact of a sensor device or control device. In this case, an end portion of the flexible film is electrically contacted by heat input at a contact point, wherein the end portion of the flexible film is placed against protruding electrical contacts at the contact point. The end portion of the flexible film is designed with a breaking wave shape, in particular as a deflection.

### SUMMARY

According to an example embodiment of the present invention, a power module is provided, having a first circuit carrier containing a carrier substrate, having a first conductor structure having an external contact region, at least one second conductor structure having at least one external contact region and a further, third conductor structure comprising an external contact region, with a first group of semiconductor elements and a second group of semiconductor elements. The groups of semiconductor elements arranged in a second plane at the bottom of the power module are electrically contacted via bonding wires and/or at least one contact strip with components arranged in a first plane of a multifunctional frame, in particular a T+ bridge and/or a phase bridge.

Based on the solution provided according to the present invention, a decoupling of the arrangement plane of the semiconductor elements from a plane in which the T+ bridge and/or the phase bridge are arranged can be achieved. In particular, the contacting between the components arranged in the first or second plane is implemented using proven bonding technology.

In an advantageous example embodiment of the power module provided according to the present invention, the bonding wires and/or the at least one contact strip extend through openings from the current-conducting contact surfaces arranged in a first plane, in the form of the T+ bridge, to contact surfaces of the semiconductor elements arranged in a second plane.

In a further advantageous example embodiment of the power module proposed according to the present invention, the multifunctional frame is arranged above or below the power module as viewed in the Z direction. Based on the variability of the assembly of the multifunctional frame in relation to the power module in the Z direction, the end user requirements can be taken into account.

Advantageously, with the power module provided according to the present invention, the openings in the T+ bridge and/or the phase bridge are designed in a number corresponding to the number of semiconductor elements to be contacted.

With the power module provided according to the present invention, the bonding wires and/or the at least one contact strip are connected to connecting pads arranged on the current-conducting contact surfaces. This allows for a more robust electrical connection, since a surface with good adhesive properties can be designed on the connecting pads.

In a further advantageous design variant of the power module provided according to the present invention, this is connected to a cooling surface either via a flat sintered connection or via a flat solder/adhesive connection.

With the power module provided according to the present invention, the arrangement consisting of the equipped multifunctional frame, on the one hand, and the equipped power module, on the other hand, which are in electrical contact with one another, is enclosed by a molding compound that comprises one or more access openings.

In a further advantageous example embodiment option of the power module provided according to the present invention, the T+ bridge and the T− bridge are accommodated one above the other in a first plane of the multifunctional frame, forming a minimum distance from one another. Alternatively, it is also possible to arrange the specified components next to one another, so that the magnetic fields that arise substantially cancel one another out, as a result of which a low-inductive connection can be achieved.

In a further advantageous design variant of the power module provided according to the present invention, a bottom surface of the power module forms a second plane in which the semiconductor elements are arranged in a manner decoupled from the first plane. Based on this design variant, the current-conducting components can be relocated to the functional frame, while the semiconductor elements remain spatially separated in the power module, as a result of which valuable (chip) area of the semiconductor elements can be saved.

Based on the solution proposed according to the present invention or the design of the power module according to the present invention, active surfaces and layout surfaces for current conduction can be separated from one another. Based on the arrangement of the multifunctional frame, which can be arranged above or below the power module, for example, the current conduction is shifted from the power module to the multifunctional frame arranged above the power module. This results in an improved cooling option for the semiconductor elements. These can be transistors, flip-flops, MOSFETS, IGBTs, diodes or the like. Based on the arrangement provided according to the present invention, improved cooling can be achieved, since larger distances between the semiconductor elements can be realized. Based on the solution provided according to the present invention, it is possible to relocate current-conducting paths in the form of the T+ bridge and/or the T− bridge and/or the phase bridge with corresponding external contacting regions into the multifunctional frame above or below the power module, and to design them to be one above the other or next to one another there, in a low-inductance manner, while maintaining the smallest possible distances, since magnetic fields arising in the current-conducting paths cancel one another out. The design option of the current-conducting paths as low-inductive current paths reduces the circuit losses that arise and allows for shorter switching times.

On the basis of the decoupling of the first and second planes in the power module and in the multifunctional frame, a compact design of the power module provided according to the present invention arises. Furthermore, the selected arrangement of the two functional planes one above the other, namely the first plane, in which the semiconductor elements are arranged, and the second plane, in which the current conduction is located, can substantially improve production; the service life of the power module is also increased.

In particular, if the contacting of the semiconductor elements in the first plane along with the current-conducting contact surfaces in the second plane, i.e. within the multifunctional frame, is represented by press-fit pins, a robust electrical contacting option for the specified components arises. Furthermore, the design of press-fit pins is technically proven and can be robustly implemented in large-scale manufacturing.

Following the solution provided by the present invention, the lower side of the power module can be advantageously connected to the upper side of a cooling surface either by a flat sintered connection or by a flat solder connection or by a flat adhesive connection. All variants offer the advantage of flat contacting, as a result of which waste heat generated during operation of the semiconductor elements can be reliably dissipated.

### BRIEF DESCRIPTION OF THE DRAWINGS

The present invention is described in more detail below with reference to the figures.

FIG. 1 shows a top view of a first circuit carrier of a power module consisting of a carrier substrate and a possible arrangement option of semiconductor switches, according to an example embodiment of the present invention.

FIG. 2 shows a top view of a power module with cooling and layout areas separated from one another with laterally arranged regions for press-fit pins, according to an example embodiment of the present invention.

FIG. 3 shows an arrangement consisting of a power module accommodated on a cooling surface and a multifunctional frame arranged above it in the Z direction, according to an example embodiment of the present invention.

FIG. 4 shows the components shown in FIG. 3 in the joined state as separate components,

FIG. 5 shows an exploded view of the components accommodated in the multifunctional frame, according to an example embodiment of the present invention.

FIG. 6 shows a perspective top view of the current-conducting contact surfaces arranged in the multifunctional frame, which lie in a plane above the plane in which the semiconductor elements are arranged, according to an example embodiment of the present invention.

FIG. 7 shows a design variant of the arrangement consisting of a power module with semiconductor elements accommodated therein, contact surfaces and their electrical contacting by means of contact strips, according to an example embodiment of the present invention.

FIG. 8 shows the arrangement of a power module bridge with a plurality of power modules next to a battery system. according to an example embodiment of the present invention.

### DETAILED DESCRIPTION OF EXAMPLE EMBODIMENTS

In the following description of example embodiments of the present invention, identical or similar elements are denoted by the same reference signs, and a repeated description of these elements in individual cases is dispensed with. The drawings show the subject matter of the present invention only schematically.

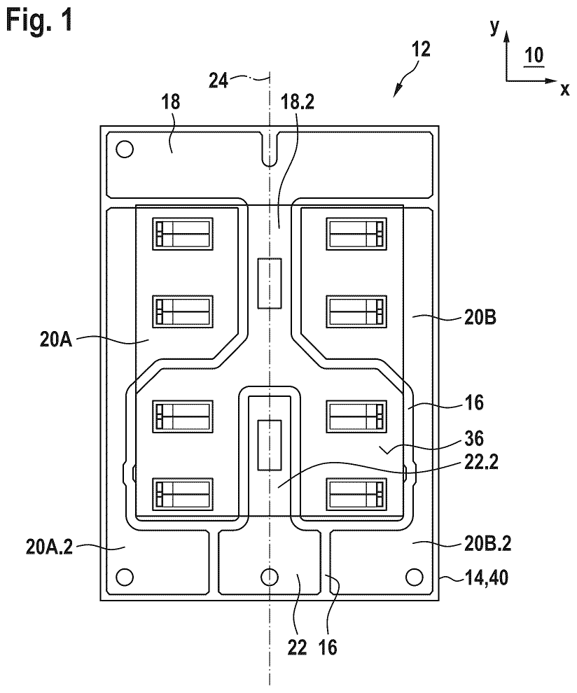

FIG. 1 is a top view of a power module 12, in particular of its first circuit carrier 14.

The top view according to FIG. 1 shows that a carrier substrate 40 of the first circuit carrier 14 is provided with a number of conductor structures 18, 20A, 20B, 22. The first circuit carrier 14 extends in an X, Y plane 10, wherein the first circuit carrier 14 is provided with an electrical insulation layer 16. A first conductor structure 18, which comprises an external contact region 18.2, is located on this, separated from one another by channel-shaped interruptions. Furthermore, second conductor structures 20A, 20B are located symmetrically to a central longitudinal axis 24 of the power module 12 opposite one another on the first circuit carrier 14. Each of the two second conductor structures 20A, 20B comprises an external contact region 20A.2, 20B.2. Finally, a third conductor structure 22 is applied to the first circuit carrier 14 or to its electrical insulation layer 16, which third conductor structure comprises at least one external contact region 22.2.

The specified conductor structures 18, 20A, 20B, 22 are electrically separated from one another and are applied to the first circuit carrier 14 substantially symmetrically with respect to the central longitudinal axis 24. An active surface is denoted by position 36, and a layout surface for the current conduction that flows around it is denoted by reference sign 38. AMB (active metal brazing) is preferably selected as the carrier substrate 40 of the first circuit carrier 14, comprising an OFC (oxygen-free copper, Si₃N₄/OFC layers).

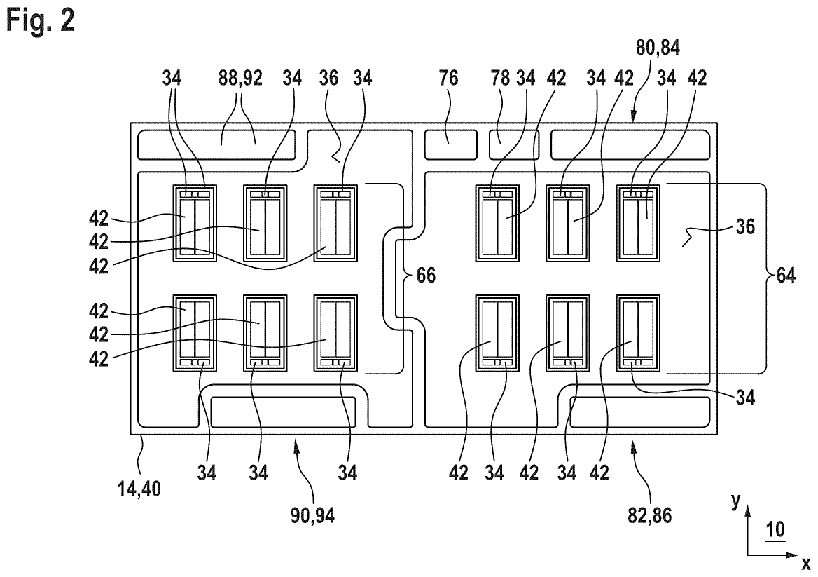

The representation according to FIG. 2 is a top view of the power module 12, wherein in this schematic representation semiconductor elements 42 are arranged on active surfaces 36, which semiconductor elements can be transistors, MOSFETs or other semiconductor elements that can be used as semiconductor switches, for example. FIG. 2 shows that, on the one hand, a first group 64 of semiconductor elements 42 is accommodated on the active surfaces 36. The individual semiconductor elements 42 can, for example, be designed as MOSFETs and comprise control terminals 34 on their outer sides, via which a control of the individual semiconductor elements 42 of the first group 64 of semiconductor elements 42, which is not shown in detail, can be effected. Analogously to the first group 64, a second group 66 of semiconductor elements 42 is arranged, which can also be MOSFETs, on the outer region of which control terminals 34 are formed in each case. The semiconductor elements 42 of the second group 66 of semiconductor elements 42 can be controlled from the outside via the control terminals 34, but this is not shown in detail in the representation according to FIG. 2.

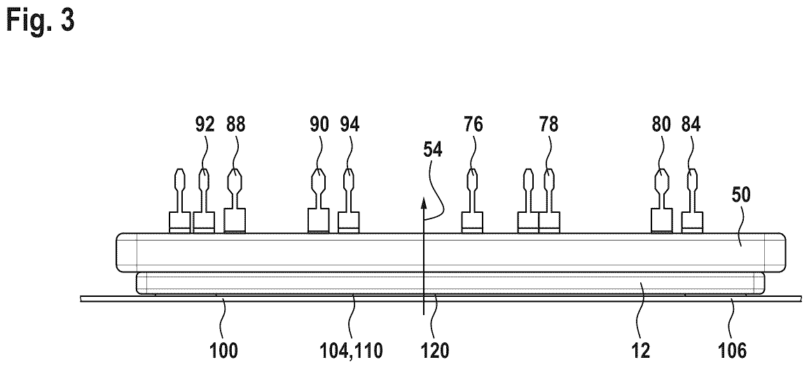

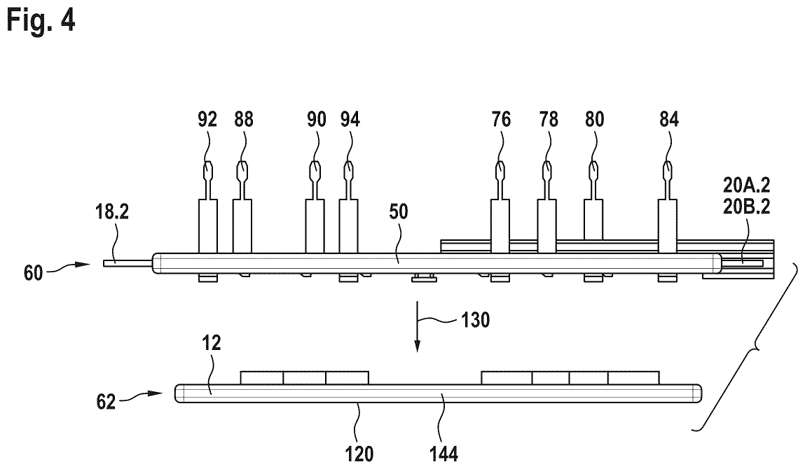

Furthermore, the top view according to FIG. 2 shows that, in the X, Y plane 10 shown in FIG. 2, regions are provided on the longitudinal sides of the first circuit carrier 14 in the form of a carrier substrate 40, in which regions press-fit pins 76-94 protrude into the drawing plane according to FIG. 2. In detail, these are first and second press-fit pins 76, 78 along with third and fourth press—|fit pins 80, 82 and, arranged opposite one another, fifth and sixth press-fit pins 84, 86. Seventh and eighth press-fit pins 88, 90 and ninth and tenth press-fit pins 92, 94 are provided in the region of the opposite end face of the first circuit carrier 14. The spatial arrangement of the press-fit pins 76, 78, 80, 82, 84, 86, 88, 90, 92, 94 can be seen in more detail in the representations according to FIGS. 3 and 4.

The side view according to FIG. 3 shows that a power module 12, shown here from the outer side, is accommodated with its lower side 120 on a cooling surface 106. As viewed in the Z direction 54, a multifunctional frame 50 is located above the power module 12. The individual press-fit pins 76, 78, 80, 82, 84, 86, 88, 90, 92, 94—shown here lying in a drawing plane-protrude upwards in the vertical direction on the upper side of the multifunctional frame 50 shown from the side in FIG. 3. Via the press-fit pins 76-94, the components arranged within the multifunctional frame 50 or the power module 12 arranged below it can be electrically contacted in a robust and simple manner.

FIG. 4 shows the components shown in FIG. 3 in the joined state as separate components. On the multifunctional frame 50, which is mounted in an assembly direction 130, for example on the upper side of the power module 12, the press-fit pins 76-94 projecting over the upper side are located analogously to FIG. 3. Laterally, the multifunctional frame 50 comprises the external contact region 18.2 along with the external contact regions 20A.2, 20B.2, which partially project into the drawing plane according to FIG. 4. The multifunctional frame 50 forms a first plane 60, in which current-conducting components in the form of a T+ bridge 134, a phase bridge 136 and a T− bridge 138 are relocated, as will be described below. The multifunctional frame 50, which is applied with its lower side 120 to the cooling surface 106 according to FIG. 3 with the interposition of further layers, accommodates a number of semiconductor elements 42 arranged individually or in groups on its bottom 144. The multifunctional frame 50 forms a second plane 62. As an alternative to the representation according to FIG. 4, it is also possible to swap the arrangement of the first and second planes 60, 62, so that the power module 12 is located above the multifunctional frame 50.

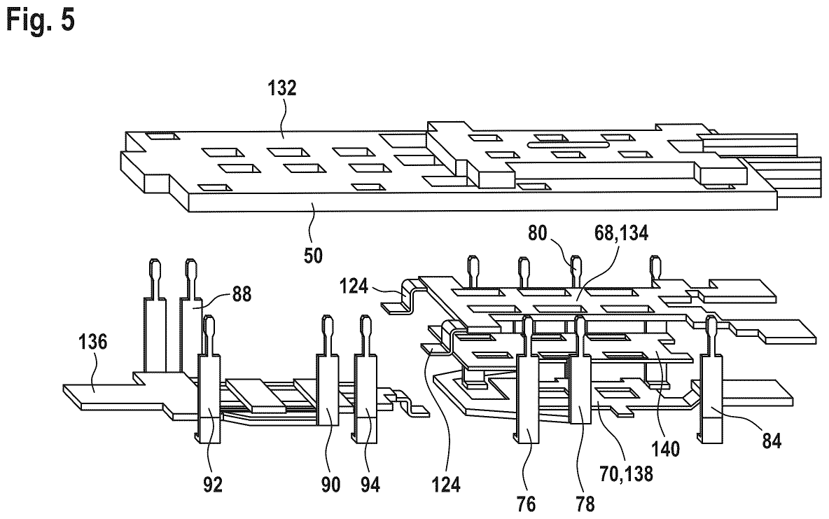

FIG. 5 shows an exploded view of the components accommodated on the multifunctional frame 50.

FIG. 5 shows that the multifunctional frame 50, which is made of a plastic material 132, accommodates the aforementioned phase bridge 136, as well as the T+ bridge 134 and the T− bridge 138 arranged below it in this design variant. The T+ bridge 134 and the T− bridge 138 are separated from one another by an insulating layer 140, which can be made of paper or cardboard. With the arrangement shown in the exploded view according to FIG. 5, the T+ bridge 134 and the T− bridge 138 extend one above the other, i.e. in a horizontal arrangement. If the distance between these two components is selected to be small, the magnetic fields that arise during operation cancel one another out in an advantageous way, so that a low-inductive connection is achieved that makes short switching times possible. Instead of the substantially horizontal arrangement of the components T+ bridge 134 and T− bridge 138 one above the other shown in the exploded view according to FIG. 5, they can also be arranged vertically, laterally or at an angle to one another. It is crucial that a small distance is maintained between these two components so that the mutual cancellation of the magnetic fields outlined above occurs during operation and a low-inductive connection is effected. Furthermore, it can be seen from the representation according to FIG. 5 that contact strips 124 are located on one end face of the T+ bridge 134, which can be connected, for example, to the bottom 144 of the power module 12, below which the cooling surface 106 is located, in order to improve heat dissipation. Furthermore, in the exploded view according to FIG. 5, a plurality of the press-fit pins 76-94 are shown, via which individual components of the multifunctional frame 50, shown and not shown, can be electrically contacted.

It should be noted that in FIG. 5, the T+ bridge 134 corresponds to the first current-conducting contact surface 68, whereas the T− bridge 138 shown below it represents the second current-conducting contact surface 70. These designations are used synonymously for the respective components.

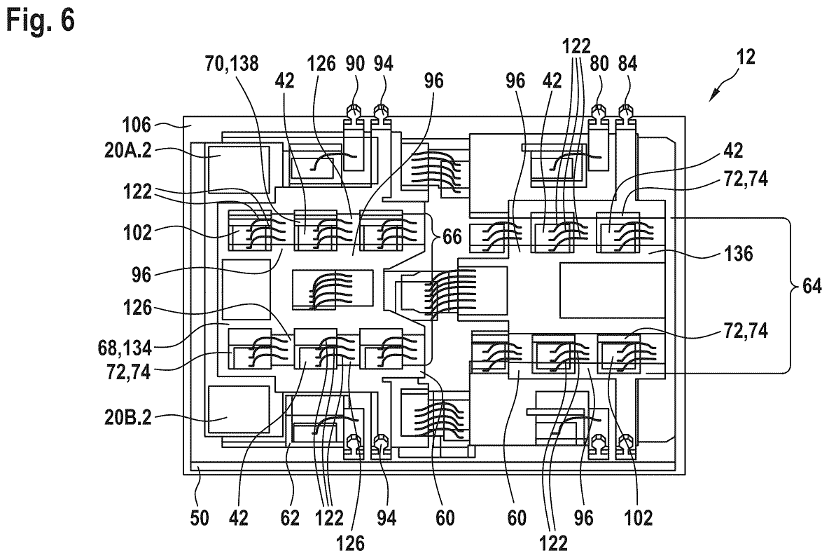

FIG. 6 shows a perspective top view of the arrangement of a multifunctional frame 50, which extends above a power module 12 with groups 64, 66 of semiconductor elements 42 arranged on its bottom 144. The number of press-fit pins 80, 82, 84, 86, 88, 90, 92, 94 shown in FIG. 3 is not necessarily the same as the number of press-fit pins 80, 84, 90, 94 shown in FIG. 6. The perspective top view according to FIG. 6 shows that the phase bridge 136 comprises, for example, two opposing fifth press-fit pins 84, via which it is contacted. Similarly, the T+ bridge 134 according to FIG. 6, which corresponds to the first current-conducting contact surface 68, also comprises tenth press-fit pins 94 arranged opposite one another, via which the underlying T− bridge 138 (second current-conducting contact surface 70) is electrically contacted. Furthermore, as can be seen from the representation according to FIG. 6, openings 72 are formed in the T+ bridge 134 and the phase bridge 136, which may have a rectangular shape 74, for example, but could also be designed to be square or circular. The number of openings 72 in the T+ bridge 134 or the phase bridge 136, both of which are arranged in the first plane 60, corresponds to the number of semiconductor elements 42 that are accommodated individually or in groups in the second plane 62, preferably at the bottom 144 of the power module 12. Furthermore, as can be seen from the representation according to FIG. 6, in this design variant the semiconductor elements 42 of the first group 64 are electrically contacted via bonding wires 122 with contact surfaces 102 that are located on the surface of the semiconductor elements 42. The bonding wires 122 extend from connecting pieces 96 of the first contact surface 68 in the first plane 60 into the second plane 62, in which the contact surfaces 102 are located on the upper side of the semiconductor elements 42.

Analogously to this electrical interconnection, the second group 66 of semiconductor elements 42 is also electrically connected via bonding wires 122, which extend from connecting pads 126 in the first plane 60 to the second plane 62 to the upper side of the contact surfaces 102 of the semiconductor elements 42. As FIG. 6 shows, the connecting pads 126 are connected on the upper side of connecting pieces 96, which separate the individual openings 72 from one another. The connecting pads 126 can comprise specially treated surfaces on which the bonding wires 122 according to FIG. 6 are contacted more robustly. The openings 72 shown in the T+ bridge 134 or the phase bridge 136, whether designed in rectangular form 74 or in another geometry, can for example be punched out in a simple manner in terms of manufacturing. Due to the bonding wires 122, the electrical contacting between the current-conducting T+ bridge 134 in the first plane 60 and the semiconductor elements 42 arranged in the second plane 62, preferably at the bottom 144 of the power module 12, is realized at their contact surface 102. The waste heat generated by the semiconductor elements 42 during operation can be dissipated from the lower side 120 of the power module 12 to a cooling surface 106 via a flat sintered connection 104 shown in FIG. 3 or alternatively via a solder/adhesive connection 110, so that steady cooling of the semiconductor elements 42, whether arranged in groups 64, 66 or individually at the bottom 144 of the power module 12, is ensured.

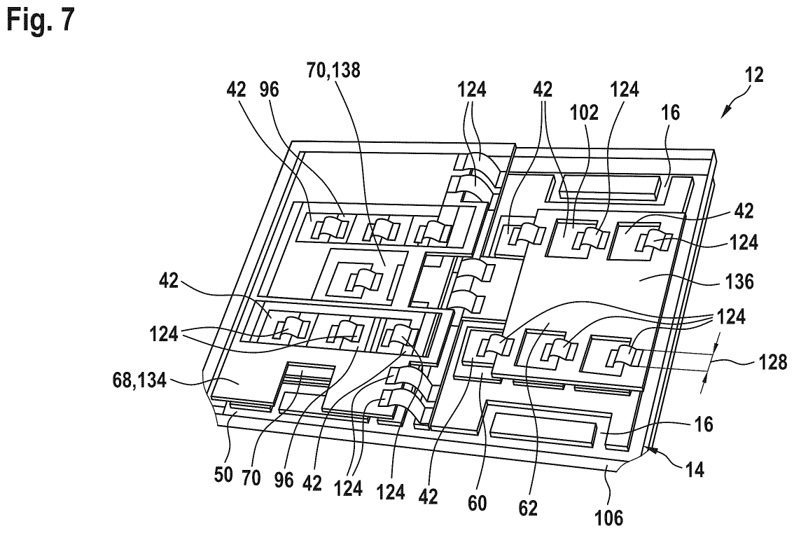

The representation according to FIG. 7 shows a further design variant of the solution proposed according to the present invention. In this design variant, it is shown that the current-conducting components, T+− bridge 134 and phase bridge 136, located in the first plane 60, are in each case electrically connected to the contact surfaces 102 of the semiconductor elements 42 arranged in the second plane 62, preferably at the bottom 144 of the power module 12, via contact strips 124, which have a width 128. The contact strips 124 shown in the perspective top view according to FIG. 7 can be connected via solder connections to the connecting pieces 96 of the current-conducting T+ bridge 134 and the phase bridge 138, on the one hand, and, on the other hand, to the contact surfaces 102 formed on the upper side of the semiconductor elements 42 to be contacted. In the design variant according to FIG. 7, the T− bridge 138, which is enclosed by the multifunctional frame 50 and which is located in the first plane 60, is substantially covered by the T+ bridge 134. This is also electrically contacted via a number of contact strips 124, for example with the first circuit carrier 14 or its conductor structures 18, 20A, 20B or 22 or the external contact regions 18.2, 20A. 2, 20B.2 or 22.2 shown in FIG. 1.

In the design variant according to FIG. 7 as well, openings 72 are punched into the current-conducting components T+ bridge 134 and phase bridge 136, which are located in the first plane 60, which openings can be formed, for example, in a rectangular shape 74 or in any other geometry. The number of openings 72 in the current-conducting components T+ bridge 134 and phase bridge 136 advantageously corresponds to the number of semiconductor elements 42 to be electrically contacted via the contact strips 124 on the contact surface 102, whether arranged in groups 64, 66 or individually distributed at the bottom 144 of the power module 12. In the variant according to FIG. 7 as well, the cooling surface 106 is located on the lower side 120 of the power module 12, which can be connected to the bottom 144 of the power module 12 either via the aforementioned sintered connection 104 or alternatively via a solder/adhesive connection 110.

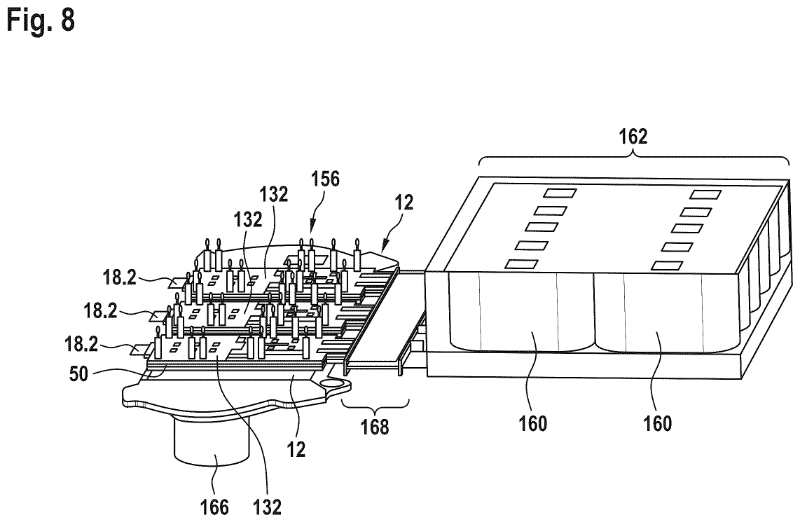

FIG. 8 shows the arrangement of a power module bridge 156 with a plurality of power modules 12 next to a battery system 162.

FIG. 8 shows that a plurality of power modules 12 are arranged next to one another on the upper side of the cooling surface 106. At one end of the power module 12, the external contact regions 18.2 are available for electrical contacting from the outside. In this case, the power module bridge 156 according to the perspective representation in FIG. 8 comprises three power modules 12 arranged next to one another. The power modules 12 are accommodated with their lower side 120 on the upper side of the cooling surface 106, so that the semiconductor elements 42 accommodated in the power modules 12 on their bottom are continuously cooled. By means of a connection device 168, the power module bridge 156 is connected to a battery system 162, of which only two battery cells 160 next to one another are arranged in a schematic manner. The connection device 168 is designed so that a lateral connection 164 arises between the power module bridge 156 and the battery system 162. Alternatively, it is possible to arrange the power module bridge 156—not shown in the drawing—above or also below the battery system 162 with a corresponding modification of the connection device 168. On the upper side of the power module bridge 156, the covers made of plastic material 132, which cover each of the multifunctional frames 50, can be seen. The press-fit pins of the multifunctional frame 50 project from the covers made of plastic material 132 in accordance with the assembly pattern for electrical contacting selected in each case.

The present invention is not limited to the embodiments described here and the aspects emphasized therein. Rather, a large number of modifications are possible within the range of the present invention, which are within the scope of the activities of a person skilled in the art.

1-9. (canceled)

10. A power module, comprising:
a first circuit carrier including a carrier substrate, a first conductor structure having an external contact region, at least one second conductor structure having at least one external contact region, and a further, third conductor structure including an external contact region;
a first group of semiconductor elements and a second group of semiconductor elements, wherein the first and second groups of semiconductor elements are arranged in a second plane at a bottom of the power module and are electrically contacted via bonding wires and/or at least one contact strip with a T+ bridge and/or phase bridge arranged in a first plane of a multifunctional frame.

11. The power module according to claim 10, wherein the bonding wires and/or the at least one contact strip extend through openings of the T+ bridge or the phase bridge, to contact surfaces of the semiconductor elements.

12. The power module according to claim 10, wherein the multifunctional frame is arranged above or below the power module as viewed in a Z direction.

13. The power module according to claim 10, wherein a number of the openings in the T+ bridge and/or the phase bridge correspond to a number of semiconductor elements to be contacted.

14. The power module according to claim 10, wherein the bonding wires and/or the at least one contact strip are connected to connecting pads of the T+ bridge and/or a T− bridge.

15. The power module according to claim 10, wherein the power module is connected to a cooling surface: (i) via a flat sintered connection or (ii) via a flat solder/adhesive connection.

16. The power module according to claim 10, wherein an arrangement including the multifunctional frame and the power module, which are in electrical contact with one another, is enclosed by a molding compound that includes one or more access openings.

17. The power module according to claim 10, wherein the T+ bridge and a T− bridge are accommodated one above the other in the first plane of the multifunctional frame, forming a minimum distance from one another.

18. The power module according to claim 10, wherein a bottom of the power module forms the second plane in which the semiconductor elements are arranged in a manner decoupled from the first plane.
